(19) United States
(12) Patent Application Publication
(10) Pub. No.: US 2010/0314695 A1
(43) Pub. Date: Dec. 16, 2010

(54) Self-aligned vertical group III-V transistor and method for fabricated same

(75) Inventor: Igor Bol, Sherman Oaks, CA (US)

Correspondence Address: FARJAMI & FARJAMI LLP, 26522 LA ALAMEDA AVENUE, SUITE 360, MISSION VIEJO, CA, 92691, US

(73) Assignee: INTERNATIONAL RECTIFIER CORPORATION, EL SEGUNDO, CA (US)

(21) Appl. No.: 12/456,064

(22) Filed: Jun. 10, 2009

(51) Int. Cl. H01L 29/78; H01L 21/336; H01L 29/20

(52) U.S. Cl. 257/409; 438/285; 257/76; 257/E29.255; 257/E21.409; 257/E29.089

(57) ABSTRACT

In one embodiment a self-aligned vertical group III-V transistor comprises a group III-V layer having a first conductivity type formed over a group III-V drift body having a second conductivity type opposite the first conductivity type, a pinch-off region formed by dopant implantation of the group III-V layer. The pinch-off region is doped so as to have the second conductivity type, and extends through the group III-V layer to the group III-V drift body. The self-aligned vertical group III-V transistor also comprises a pinch-off insulation body formed over the pinch-off region, the pinch-off region and the pinch-off insulation body being self-aligned. In one embodiment, the present invention may take the form of a self-aligned vertical N-channel field-effect transistor (FET) in gallium nitride GaN.

### DEFINITION

In the present application, “group III-V semiconductor” refers to a compound semiconductor that includes at least one group III element and at least one group V element, such as, but not limited to, gallium nitride (GaN), gallium arsenide (GaAs), aluminum gallium arsenide (AlGaAs), indium gallium nitride (InGaN) and the like. Analogously, “III-nitride semiconductor” refers to a compound semiconductor that includes nitrogen and at least one group III element, such as, but not limited to, GaN, AlGaN, InN, AlN, InGaN, InAlGaN and the like.

### BACKGROUND OF THE INVENTION

1. Field of the Invention

The present invention is generally in the field of semiconductors. More specifically, the present invention is in the field of fabrication of semiconductor transistors.

2. Background Art

Many prevalent electronic devices and systems continue to require faster switching speeds and greater power handling capabilities. Examples of such electronic devices and systems are semiconductor based switching and amplification devices employed in, for example, wireless communications such as W-CDMA (wideband code division multiple access) base stations and the like.

One response to these increased device performance demands has been the development and implementation of transistors formed from group III-V compound semiconductor materials. For example gallium nitride (GaN) and other III-nitride semiconductors are now frequently used in the fabrication of high electron mobility transistors (HEMTs) and metal-insulator-semiconductor field-effect transistors (MISFETs), displaying favorable power handling characteristics. In a typical GaN MISFET, for example, power electrodes connected to respective highly doped source and drain regions are laterally separated on a common surface of a GaN body, and have an insulated gate structure formed between them. The distance from one power electrode, e.g., the source electrode, to the second power electrode, e.g., the drain electrode, corresponds to a MISFET cell width providing a measure of the GaN body surface area required to support a single MISFET.

In practice, the power handling capability of a GaN MISFET depends in part on its cell width. In particular, the breakdown voltage of the described laterally arranged MISFET is proportional to its cell width, which may range from approximately ten to thirty microns, depending upon the breakdown voltage requirements of the device. Thus, in a conventional lateral MISFET architecture, cell width, and consequently the surface area consumed on the GaN body by the MISFET, must increase to accommodate higher voltage applications. However, the increased performance requirements imposed on modem electronic devices requires reductions in device size and increases in device densities, as well as increased power handling capabilities. As a result, the laterally arranged configuration adopted in conventional group III-V transistor design, which requires ever greater cell widths to provide increased voltage breakdown resistance, represents an undesirable solution to present and future device requirements.

Thus, there is a need to overcome the drawbacks and deficiencies in the art by providing a group III-V transistor capable of withstanding high voltage operation while occupying a reduced surface area so as to enable high device densities.

### SUMMARY OF THE INVENTION

A self-aligned vertical group III-V transistor and method for fabricating same, substantially as shown in and/or described in connection with at least one of the figures, as set forth more completely in the claims.

### BRIEF DESCRIPTION OF THE DRAWINGS

FIG. 1 shows a flowchart presenting a method for fabricating a self-aligned vertical group III-V transistor, according to one embodiment of the present invention.

FIG. 2A shows a cross-sectional view of a structure representing a self-aligned vertical group III-V transistor at an initial fabrication stage, according to one embodiment of the present invention.

FIG. 2B shows a cross-sectional view of a structure representing a self-aligned vertical group III-V transistor at an intermediate fabrication stage, according to one embodiment of the present invention.

FIG. 2C shows a cross-sectional view of a structure representing a self-aligned vertical group III-V transistor at an intermediate fabrication stage, according to one embodiment of the present invention.

FIG. 2D shows a cross-sectional view of a structure representing a self-aligned vertical group III-V transistor at an intermediate fabrication stage, according to one embodiment of the present invention.

FIG. 2E shows a cross-sectional view of a structure representing a self-aligned vertical group III-V transistor at an intermediate fabrication stage, according to one embodiment of the present invention.

FIG. 2F shows a cross-sectional view of a structure representing a self-aligned vertical group III-V transistor at a final fabrication stage, according to one embodiment of the present invention.

### DETAILED DESCRIPTION OF THE INVENTION

The present invention is directed to a self-aligned vertical group III-V transistor and a method for its fabrication. Although the invention is described with respect to specific embodiments, the principles of the invention, as defined by the claims appended herein, can obviously be applied beyond the specifically described embodiments of the invention described herein. Moreover, in the description of the present invention, certain details have been left out in order to not obscure the inventive aspects of the invention. The details left out are within the knowledge of a person of ordinary skill in the art.

The drawings in the present application and their accompanying detailed description are directed to merely example embodiments of the invention. To maintain brevity, other embodiments of the invention, which use the principles of the present invention, are not specifically described in the present application and are not specifically illustrated by the present drawings. It should be borne in mind that, unless noted otherwise, like or corresponding elements among the figures may be indicated by like or corresponding reference numerals.

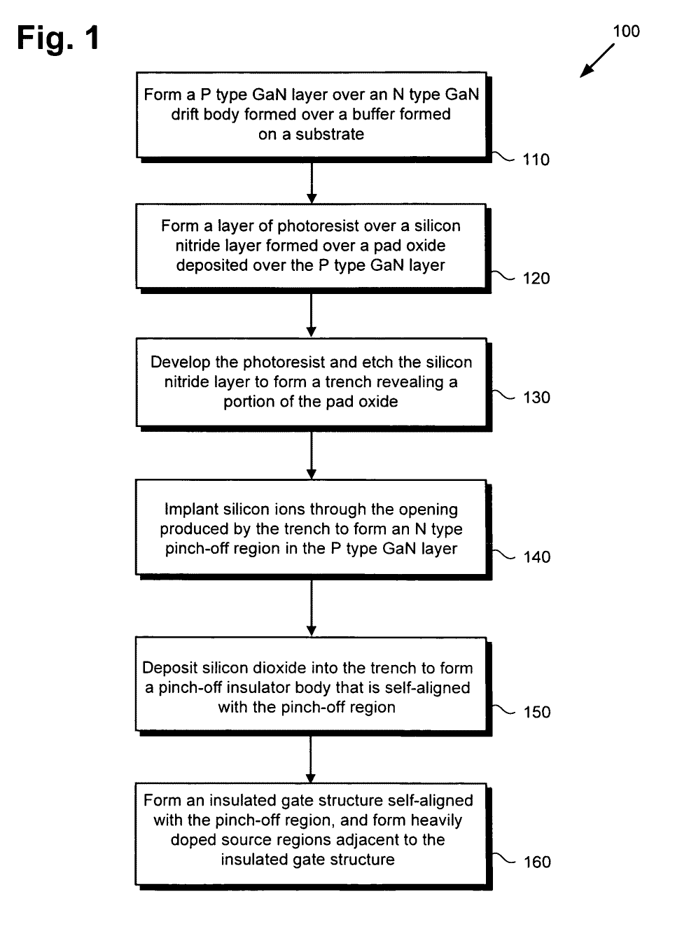

FIG. 1 shows a flowchart illustrating an exemplary method, according to one embodiment of the present invention, for fabricating a self-aligned vertical group III-V transistor. Certain details and features have been left out of flowchart 100 that are apparent to a person of ordinary skill in the art. For example, a step may comprise one or more substeps or may involve specialized equipment or materials, as known in the art. While steps 110 through 160 indicated in flowchart 100 are sufficient to describe one embodiment of the present invention, other embodiments of the invention may utilize steps different from those shown in flowchart 100.

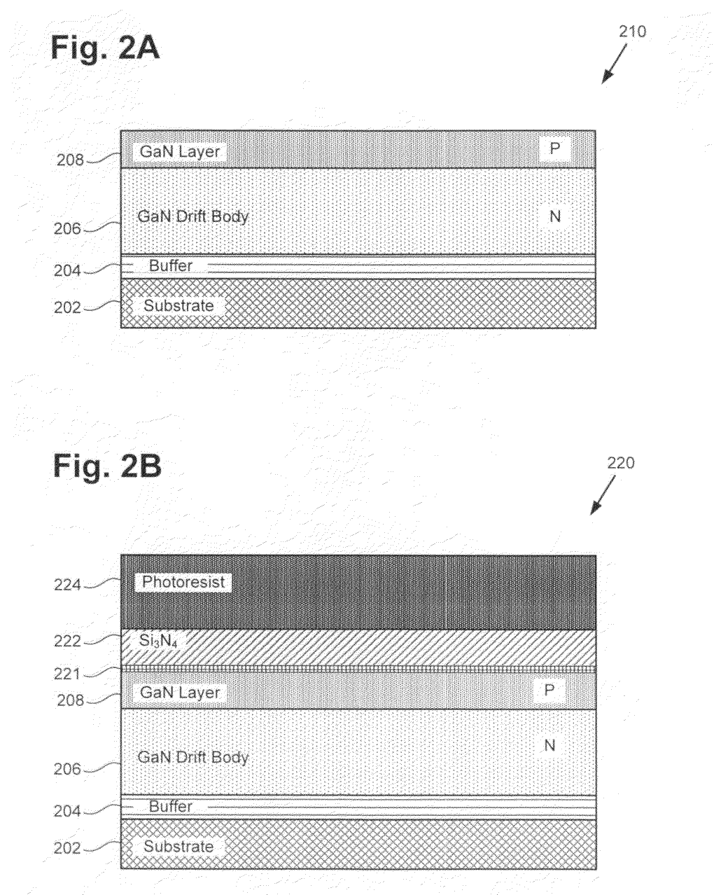

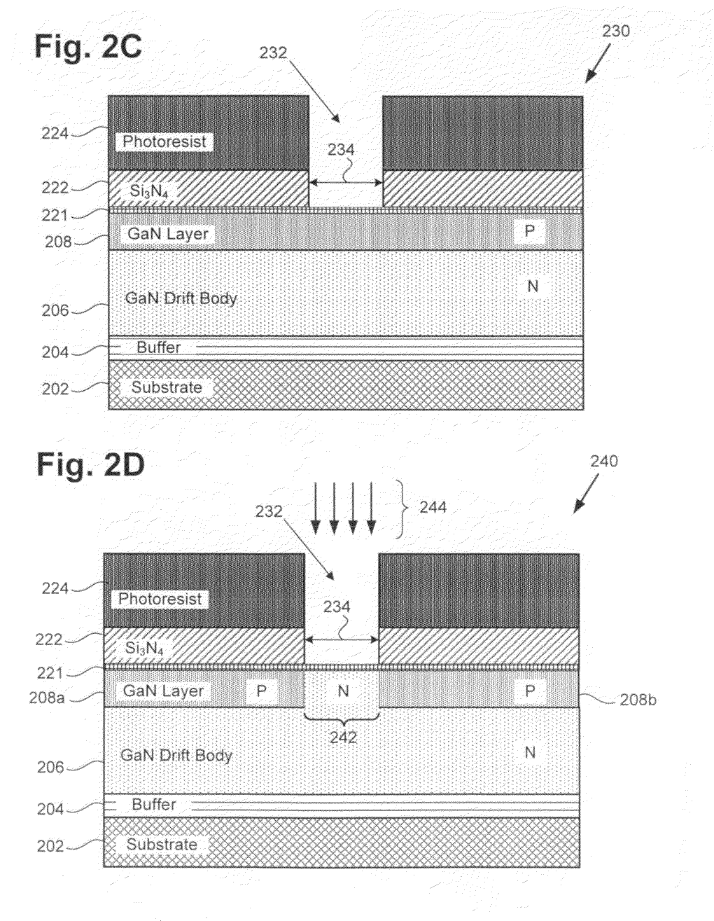

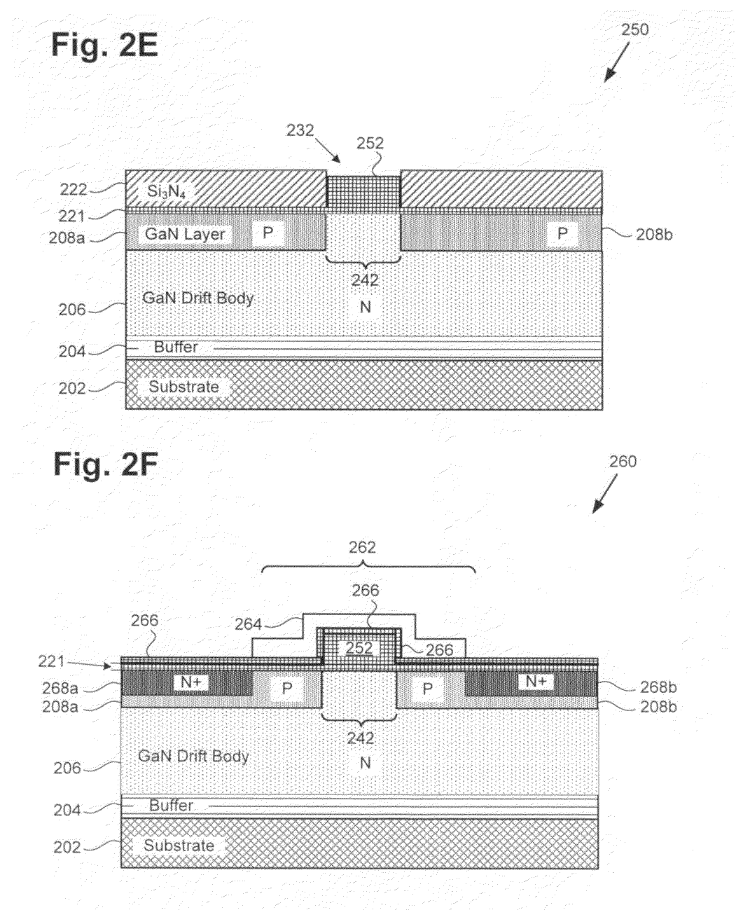

Turning now to FIG. 2A, structure 210 of FIG. 2A shows a cross-sectional view representing a self-aligned vertical group III-V transistor at an initial fabrication stage, according to one embodiment of the present invention. Structure 210 shows substrate 202, buffer 204, N type gallium nitride (GaN) drift body 206, and P type GaN layer 208, according to the embodiment shown in flowchart 100 of FIG. 1. In particular, FIG. 2A shows structure 210 at a stage of fabrication following processing step 110 of flowchart 100.

Referring to FIGS. 2B, 2C, 2D, 2E, and 2F, structures 220, 230, 240, 250, and 260 show the result of performing, on structure 210, steps 120, 130, 140, 150, and 160 of flowchart 100 of FIG. 1, respectively. For example, structure 220 shows structure 210 following processing step 120, structure 230 shows structure 210 following processing step 130, and so forth.

It is noted that the structures shown in FIGS. 2A through 2F are provided as specific implementations of the present inventive principles, and are shown with such specificity for the purposes of conceptual clarity. It should further be understood that particular details such as the materials used to form structures 210 through 260, the semiconductor devices represented by those fabrication stages, and the techniques used to produce the various depicted features, are being provided as examples, and should not be interpreted as limitations. For example, although the embodiments shown in FIGS. 2A through 2F represent fabrication of an N-channel field-effect transistor (FET) in GaN, other embodiments of the present invention may correspond to P-channel devices, formed using GaN or any other suitable group III-V semiconductor materials, as described in the “Definition” section above.

Beginning with step 110 in FIG. 1 and structure 210 in FIG. 2A, step 110 of flowchart 100 comprises forming P type conductivity GaN layer 208 over N type conductivity GaN drift body 206, formed over buffer 204 formed on substrate 202. Substrate 202 may comprise any commonly utilized substrate material for GaN, such as sapphire, silicon, or silicon carbide, for example. As shown by FIG. 2A, in the present embodiment, GaN drift body 206 is formed over buffer 204, which is itself formed over substrate 202. It is noted that the present embodiment is merely one representation of a group III-V semiconductor structure, however, and in other embodiments, buffer 204 may not be utilized. For example, where substrate 202 is a suitable native substrate for GaN drift body 206, GaN body drift body 206 may be formed on substrate 202, eliminating buffer 204 entirely.

Where, however, as in the present embodiment, buffer 204 is used, buffer 204 may correspond to a plurality of distinguishable layers mediating the lattice transition from substrate 202 to GaN drift body 206. Buffer 204 may include, for example, an aluminum nitride (AlN) layer followed by a series of layers comprising AlN and GaN, with each progressive layer comprising less aluminum and more gallium until a suitable transition to GaN drift body 206 is achieved. GaN drift body 206 may be formed over buffer 204 using any of a number of conventional growth techniques. For example, GaN drift body 206 may be formed using molecular-beam epitaxy (MBE), metalorganic chemical vapor deposition (MOCVD), or hydride vapor phase epitaxy (HVPE), to name a few suitable approaches. Although the embodiment of structure 210 contemplates growth of GaN drift body 206 to a thickness of approximately three to four microns, for example, other embodiments may include a substantially thicker GaN drift body. As shown in FIG. 2A, GaN drift body 206 is N type doped. N type doping of GaN drift body 206 may be performed in situ, for example, by incorporation of suitable dopant ions, such as silicon ions, during GaN growth.

Similarly, GaN layer 208 may be formed over GaN drift body 206 using any of MBE, MOCVD, or HVPE, for example. It is contemplated that GaN layer 208 may be grown to a thickness of approximately one micron, but as is the case for GaN drift body 206, in other embodiments, GaN layer 208 may assume other thicknesses, greater than or less than the exemplary thickness of approximately one micron described herein. Again, as for GaN drift body 206, doping of GaN layer 208 may be accomplished in situ, by incorporation in this instance of suitable P type dopant ions, such as magnesium ions, during growth of GaN layer 208. It is emphasized that the example structure shown by FIG. 2A contemplates fabrication of an N-channel transistor. In other embodiments, however, a P-channel device may be desired, in which cases GaN drift body 206 may formed so as to be P type, while GaN layer 208 may be formed to be N type.

Continuing on to step 120 in FIG. 1 and structure 220 in FIG. 2B, step 120 of flowchart 100 comprises forming photoresist layer 224 over silicon nitride (Si₃N₄) layer 222 formed over pad oxide 221 deposited over P type GaN layer 208. Pad oxide 221 may be any suitable barrier oxide, such as silicon dioxide (SiO₂), for example. It is also noted that Si₃N₄ layer 222 is merely an example of a suitable dielectric layer, and in other embodiments may comprise an oxide such as SiO₂. In the present example, it is contemplated that pad oxide 221 has a thickness of approximately 400 Å. It is further contemplated that Si₃N₄ layer 222 is deposited to a thickness of approximately 5000 Å, using a plasma enhanced chemical vapor deposition (PECVD) process. In other embodiments, however, other suitable deposition techniques may be utilized, and the thicknesses of pad oxide 221 and/or Si₃N₄ layer 222 may be varied according to the specific device dimensions. For example, in some embodiments, the thickness of Si₃N₄ layer 222 may be selected according to the thickness of GaN layer 208.

Photoresist layer 224 can comprise a polymer matrix and one or more catalytic species. The polymer matrix can comprise an organic polymer material comprising styrene, acrylate, or methacrylate monomers, for example. In other embodiments, photoresist layer 224 can comprise different organic or inorganic polymers. The catalytic species present in photoresist layer 224 may be, for example, an acid, base, or oxidizing agent, activated by exposure to patterned radiation. Photoresist layer 224 can be formed by any suitable deposition process, as known in the art. Although the present embodiment contemplates photoresist layer 224 having a thickness of approximately three to four microns, as is the case for Si₃N₄ layer 222, in other embodiments the thickness of photoresist layer 224 may vary considerably depending upon other device dimensions, such as the thickness of GaN layer 208.

Referring to step 130 of FIG. 1 and structure 230 in FIG. 2C, step 130 of flowchart 100 comprises developing photoresist layer 224 and etching Si₃N₄ layer 222 to form trench 232 revealing a portion of pad oxide 221. Trench 232 may be formed through Si₃N₄ layer 222 using a plasma etch, or other suitable technique, and may be formed so as to have a width (234) of from approximately 2000 Å to approximately 5000 Å, for example.

Continuing with step 140 of flowchart 100 and structure 240 in FIG. 2D, step 140 of flowchart 100 comprises implanting silicon ions through the opening produced by trench 232 to form N type pinch-off region 242 in P type GaN layer 208. As shown in FIG. 2D, in some embodiments, N type pinch-off region 242 extends through P type GaN layer 208 to N type GaN drift body 206. In those embodiments, as further shown in FIG. 2D, step 140 may result in a partitioning of P type GaN layer 208 into distinct P type GaN regions 208a and 208b, separated by N type pinch-off region 242. As mentioned, although the present embodiment represents formation of an N type pinch-off region consistent with an N-channel device, in another embodiment, a P type pinch-off region could be formed through, for example, implantation of magnesium ions into an N type GaN layer formed over a P type GaN drift body.

Referring back to structure 220 in FIG. 2B in light of step 140, it may now be seen that that the thicknesses of respective Si₃N₄ layer 222 and photoresist layer 224 may be selected so as to provide adequate masking of P type GaN regions 208a and 208b during formation of pinch-off region 242, shown in FIG. 2D. In so far as the required implantation depth may vary according to the thickness of GaN layer 208, the thicknesses of respective silicon nitride layer 222 and photoresist layer 224 may also be variable according to the thickness of GaN layer 208.

Moving on to structure 250 in FIG. 2E and step 150 in FIG. 1, step 150 of flowchart 100 comprises depositing SiO₂ into trench 232 to form pinch-off insulation body 252. As can be seen from FIG. 2E, step 150 may be preceded by removal of photoresist layer 224, leaving trench 232 having width 234 in Si₃N₄ layer 222. Because trench 232 having width 234 is used to define the lateral dimensions of both pinch-off region 242 and pinch-off insulation body 252, those features are self-aligned. It is noted that the transition from the structures shown respectively in FIGS. 2D and 2E may further include PECVD deposition of SiO₂ to a thicknesses of approximately 6000 Å, for example, followed by a back etch resulting in formation of pinch-off insulation body 252 in trench 232.

The use of SiO₂ to form pinch-off insulation body 252 corresponds more generally to deposition of any suitable dielectric into trench 232 to form pinch-off insulation body 252. Thus, in other embodiments pinch-off insulation body 252 may comprise an insulating nitride, such as Si₃N₄, for example. It is noted that it may be advantageous for the dielectric materials selected for use in forming layer 222 and pinch-off insulation body 252 to be different from one another. For example, utilizing different dielectric materials for layer 222 and pinch-off insulation body 252 permits subsequent removal of layer 222 without compromising the dimensional integrity of pinch-off insulation body 252, e.g., its self-alignment with pinch-off insulation region 242.

Continuing with step 160 of flowchart 100 and structure 260 in FIG. 2F, insulated gate structure 262 self-aligned with pinch-off region 242, and heavily doped N type source regions 268a and 268b adjacent to insulated gate structure 262 are formed. As shown in FIG. 2F, insulated gate structure 262 comprises gate 264, and gate insulation layer 266 conformally deposited over pinch-off insulation body 252 and pad oxide 221 formed over GaN regions 208a and 208b. In one embodiment, as shown in FIG. 2F, gate insulation layer 266 may comprise the same dielectric material used to form pinch-off insulation body 252 and pad oxide 221, e.g., SiO₂, and may be deposited to a thickness or approximately 400 Å, for example. In other embodiments, however, gate insulation layer 266 may comprise a different dielectric material than that used to form pinch-off insulation body 252 and/or pad oxide 221, and may be formed using a nitride such as Si₃N₄, AlN, BN, or the like, for example.

Gate 264 may comprise doped polysilicon, for example, and may be conformally deposited over gate insulation layer 266, as is further shown in FIG. 2F. Because in some embodiments, formation of gate 264 is conformal with respect to gate insulation layer 266, itself conformally deposited over pinch-off insulation body 252, in those embodiments pinch-off region 242 is self-aligned with insulated gate structure 262.

FIG. 2F also shows heavily doped source regions 268a and 268b adjacent to insulated gate structure 262. According to the embodiment of structure 260, for example, source regions 268a and 268b may be formed through implantation of silicon ions into GaN regions 208a and 208b adjacent to gate structure 262 at a concentration of approximately (5.0×10¹⁵)/cm², and an implantation energy of approximately 150 keV, for example.

Although not shown by the present figures, fabrication of a self-aligned vertical transistor may continue with steps corresponding to activation of the dopant species, formation of gate and source contacts, removal of substrate 202 and buffer 204 from the backside of GaN drift body 206, and formation of a metal contact on the backside of GaN drift body 206 to serve as a drain contact for the self-aligned vertical transistor. As previously described, the transistor so fabricated may be a FET, such as an N-channel or P-channel MOSFET or MISFET, for example.

According to the present invention, the novel vertical self-aligned group III-V transistor described herein presents significant advantages over conventional art, such as the fact that the invention's transistor is capable of withstanding high voltages while occupying a reduced surface area so as to enable high device densities.

From the above description of the invention it is manifest that various techniques can be used for implementing the concepts of the present invention without departing from its scope. Moreover, while the invention has been described with specific reference to certain embodiments, a person of ordinary skill in the art would recognize that changes can be made in form and detail without departing from the spirit and the scope of the invention. The described embodiments are to be considered in all respects as illustrative and not restrictive. It should also be understood that the invention is not limited to the particular embodiments described herein, but is capable of many rearrangements, modifications, and substitutions without departing from the scope of the invention.

1. A self-aligned vertical group III-V transistor comprising:
a group III-V layer having a first conductivity type situated over a group III-V drift body having a second conductivity type;
a pinch-off region having said second conductivity type situated in said group III-V layer; and
an insulated gate structure being self-aligned to and situated over said pinch-off region.

2. The self-aligned vertical group III-V transistor of claim 1, wherein said pinch-off region is formed by dopant ion implantation of said group III-V layer.

3. The self-aligned vertical group III-V transistor of claim 1, wherein said pinch-off region extends to said group III-V drift body.

4. The self-aligned vertical group III-V transistor of claim 1, wherein said insulated gate structure is formed over a pinch-off insulation body that is self-aligned to and situated over said pinch-off region.

5. The self-aligned vertical group III-V transistor of claim 1, wherein said transistor is a field-effect transistor (FET).

6. The self-aligned vertical group III-V transistor of claim 1, wherein said transistor is a metal-insulator-semiconductor FET (MISFET).

7. The self-aligned vertical group III-V transistor of claim 1, further comprising a plurality of heavily doped source regions having said second conductivity type in said group III-V semiconductor layer adjacent to said insulated gate structure.

8. The self-aligned vertical group III-V transistor of claim 1, wherein said group III-V drift body and said group III-V layer comprise a III-nitride semiconductor.

9. The self-aligned vertical group III-V transistor of claim 1, wherein said group III-V drift body and said group III-V layer comprise GaN.

10. The self-aligned vertical group III-V transistor of claim 1, wherein said first conductivity type is P type and said second conductivity type is N type.

11. The self-aligned vertical group III-V transistor of claim 2, wherein said dopant ions comprise silicon ions.

12. The self-aligned vertical group III-V transistor of claim 4, wherein said pinch-off insulation body comprises silicon dioxide.

13. A method for fabricating a self-aligned vertical group III-V transistor, the method comprising:
forming a group III-V layer having a first conductivity type over a group III-V drift body having a second conductivity type;
forming a dielectric layer over said group III-V layer;
forming a pinch-off region of said second conductivity type in said group III-V layer;
forming a self-aligned insulated gate structure over said pinch-off region.

14. The method of claim 13, wherein said forming said pinch-off region comprises implanting dopant ions through an opening in said dielectric layer.

15. The method of claim 13, wherein said pinch-off region extends to said group III-V drift body.

16. The method of claim 13, wherein said transistor is a field-effect transistor (FET).

17. The method of claim 13, further comprising forming a plurality of heavily doped source regions having said second conductivity type in said group III-V semiconductor layer adjacent to said insulated gate structure.

18. The method of claim 13, wherein said group III-V drift body and said group III-V layer comprise a III-nitride semiconductor.

19. The method of claim 13, wherein said group III-V drift body and said group III-V layer comprise GaN.

20. The method of claim 14, wherein said dopant ions comprise silicon ions.
